(19) United States
(12) Patent Application Publication
(10) Pub. No.: US 2008/0075563 A1
(43) Pub. Date: Mar. 27, 2008

(54) SUBSTRATE HANDLING SYSTEM AND METHOD

(76) Inventor: James R. McLane, Beverly, MA (US)

Correspondence Address: Scott Faber, Esq.;Varian Semiconductor Equipment Associates, Inc, 35 Dory Road, Gloucester, MA, 01930, US

(21) Appl. No.: 11/535,770

(22) Filed: Sep. 27, 2006

(51) Int. Cl. H01L 21/677

(52) U.S. Cl. 414/217

(57) ABSTRACT

A system and method for handling substrates in a vacuum chamber. The system includes a first robot configured for transferring substrates from a first set of load locks to a preprocessing station, and for transferring substrates from a process platen to the first set of load locks; a second robot configured for transferring substrates from a second set of load locks to the preprocessing station, and for transferring substrates from the process platen to the second set of load locks; and a transfer mechanism for transferring substrates from the preprocessing station to the process platen.

### FIELD OF THE INVENTION

The invention relates generally to a system and method for moving workpieces in a chamber, and more particularly to a system and method for handling substrates within a vacuum chamber.

### BACKGROUND OF THE INVENTION

The processing of semiconductor wafers typically requires the application of many different types of tools to complete hundreds of processing steps in order to manufacture microelectronic circuits. Most of these processing steps must be performed in a vacuum chamber, where wafers are processed anywhere from a few seconds to many minutes. Most of the processing tools operate on wafers one at a time in order to optimize control and reproducibility in a manufacturing environment.

One of the challenges involved in manufacturing semiconductor devices involves increasing the speed at which wafers are processed. Accordingly, the ability to move wafers into and out of a vacuum chamber as efficiently as possible remains an ongoing challenge.

Current high speed wafer processing systems typically utilize one or more robots that transfer individual wafers from one or more load locks onto a platen in a process chamber where the wafer is processed. Once the processing is complete, the wafer is returned to the one or more load locks. As wafers enter and exit the process chamber, venting and pumping operations are implemented to create a vacuum in the chamber during the processing operation. In order to enhance the throughput, wafers may be temporarily placed onto a preprocessing station in the process chamber, where the wafer can be, e.g., oriented or aligned, while another wafer is being processed. An example of such a system is described in U.S. Pat. No. 5,486,080, entitled, “High Speed Movement of Workpieces in Vacuum Processing,” which issued on Jan. 23, 1996 to Sieradzki, and is hereby incorporated by reference. Other approaches include utilizing a pair of robots in the vacuum chamber, such as that disclosed in U.S. Pat. No. 7,059,817, entitled “Wafer Handling Apparatus and Method,” which issued on Jun. 13, 2006, and which is also hereby incorporated by reference. Drawbacks of U.S. Pat. No. 7,059,817 include the requirement of two preprocessing stations and limited throughput speeds since distinct wafers are handled by a distinct one of the robots within the chamber.

However, as higher and higher throughput speeds are sought, such existing systems cannot meet the demand. Accordingly, a need exists for a substrate handing system that can achieve higher throughput rates.

### SUMMARY OF THE INVENTION

The present invention addresses the above-mentioned problems, as well as others, by providing a system and method for handling substrates in a vacuum chamber. In a first aspect, the invention provides a substrate handler, having a vacuum chamber for processing a substrate in a controlled environment, the substrate handler comprising: a first robot configured for transferring substrates from a first set of load locks to a preprocessing station, and for transferring substrates from a process platen to the first set of load locks; a second robot configured for transferring substrates from a second set of load locks to the preprocessing station, and for transferring substrates from the process platen to the second set of load locks; and a transfer mechanism for transferring substrates from the transfer station to the process platen. The first and second set of load locks may each comprise two single substrate load locks configured for transitioning wafers from atmosphere to a high vacuum state, and vice versa.

In a second aspect, the invention provides a method of handling substrates in a chamber, comprising: loading a first substrate from a first set of load locks to a preprocessing station using a first robot; preprocessing the first substrate on the preprocessing station; moving the first substrate to a process platen using a transfer mechanism; loading a second substrate from a second set of load locks to the preprocessing station using a second robot; preprocessing the second substrate on the preprocessing station; processing the first substrate on the process platen; moving the first substrate to the second set of load locks using the second robot; moving the second substrate to the process platen using the transfer mechanism; processing the second substrate on the process platen; and moving the second substrate to the first set of load locks using the first robot. This interlaced method of processing substrates from alternating sides can be repeated to produce a continuous flow of substrates to and from the process platen.

In a third aspect, the invention provides a method of handling substrates in a chamber, comprising: loading a first substrate from a first set of load locks to a preprocessing station using a first robot; preprocessing the first substrate on the preprocessing station; picking the first substrate off the preprocessing station and storing the first substrate on a transfer mechanism; loading a second substrate from a second set of load locks to the preprocessing station using a second robot; preprocessing the second substrate on the preprocessing station; placing the first substrate onto a process platen from the transfer mechanism; picking the second substrate off the preprocessing station and storing it on the transfer mechanism; loading a third substrate from the first set of load locks to the preprocessing station using the first robot; and processing the first substrate on the process platen. Additional steps include: moving the first substrate to the first set of load locks using the first robot; placing the second substrate onto a process platen from the transfer mechanism; processing the second substrate on the process platen; picking the third substrate off the preprocessing station and storing it on the transfer mechanism; and moving the second substrate to the second set of load locks using the first robot. This interlaced method of processing substrates from alternating sides can be repeated to produce a continuous flow of wafers to and from the process platen.

In a fourth aspect, the invention comprises a program product stored on a computer readable medium, which when executed controls the flow of substrates within a substrate handler, the program product comprising: program code configured for causing a first robot to transfer substrates from a first set of load locks to a preprocessing station, and to transfer substrates from a process platen to the first set of load locks; program code configured for causing a second robot to transfer substrates from a second set of load locks to the preprocessing station, and to transfer substrates from the process platen to the second set of load locks; program code configured for causing a transfer mechanism to transfer substrates from the preprocessing station to the process platen; and program code configured for pumping and venting the first and second set of load locks.

### BRIEF DESCRIPTION OF THE DRAWINGS

These and other features of this invention will be more readily understood from the following detailed description of the various aspects of the invention taken in conjunction with the accompanying drawings in which:

FIG. 1 depicts a diagram of a substrate handler in accordance with an embodiment of the present invention.

FIG. 2 depicts a timing/action diagram for a first substrate flow in accordance with an embodiment of the present invention.

FIG. 3 depicts a diagram for a second substrate flow in accordance with an embodiment of the present invention.

FIG. 4 depicts a timing/action diagram for a second substrate flow in accordance with an embodiment of the present invention.

### DETAILED DESCRIPTION OF THE INVENTION

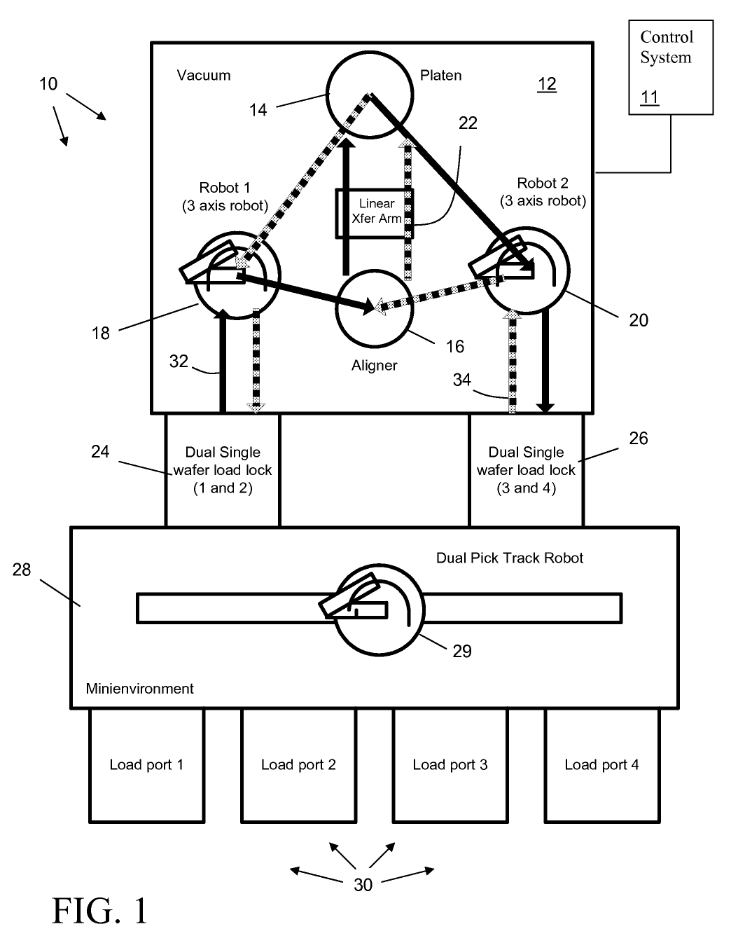

Referring now to drawings, FIG. 1 depicts a substrate handler 10 that generally includes four load ports 30, a mini-environment 28 that includes a dual pick track robot 29, two sets of load locks 24, 26, and a vacuum chamber 12. In one illustrative embodiment, each set of load locks 24, 26 comprises dual single wafer load locks, e.g., one stacked on the other for a total of four single wafer load locks. However, it should be understood that each set of load locks 24, 26 may comprise one or more load locks, and each load lock is configured for transitioning wafers from atmosphere to a high vacuum state, and vice versa. Accordingly, each load lock generally includes a pumping and venting system (not shown) for pumping down and venting the load lock.

The vacuum chamber 12 includes two 3-axis (vacuum) robots 18, 20, an aligner 16, a transfer mechanism 22, and a process platen 14. Note that while the embodiments are generally directed to the handling of wafers, the systems and methods described herein could be utilized for handling any type of substrate that needs to be processed in a controlled environment.

In the illustrative embodiments described with reference to FIG. 1, wafers move through the vacuum chamber 12 along one of two paths, shown as solid arrows 32 and dotted arrows 34. As can be seen, if a wafer enters through the first set of dual single wafer load locks 24, it exits through the second set of dual single wafer load locks 26, and vice versa.

The dual pick track robot 29 is an atmospheric robot that provides fast swapping between the load ports 30 and the sets of dual single wafer load locks 24, 26. The sets of dual single wafer load locks 24, 26 provide a transition platform for substrates (i.e., wafers) being transitioned between the vacuum chamber 12 and the atmosphere within mini-environment 28.

Each of the two vacuum robots 18, 20 are configured to: (1) pick a substrate from an associated load lock and place the substrate onto the aligner 16; and (2) pick a substrate off the process platen 14 and place it into an associated load lock. Note that the illustrative embodiments described herein utilize aligner 16 to align substrates within vacuum chamber 12. However, it is understood that aligner 16 could be replaced by another type of preprocessing station. For instance, aligner 16 could be replaced with or include an orientor for orienting the substrate, e.g., by determining centering information and notch location. If alignment and orientation are not needed, then the preprocessing station could be implemented as a simple transfer station. Moreover, the preprocessing station may also be equipped with a substrate ID reader. Accordingly, it us understood that aligner 16 could be replaced with any type of preprocessing station. Transfer mechanism 22, which may for instance comprise a linear transfer arm, picks substrates from the aligner 16 and places them onto the process platen 14. Transfer mechanism 22 may also provide temporary storage for a substrate.

Also included as part of substrate handler 10 is a control system 11 for controlling all of the operations relating to the flow of substrates. These operations include the movements of robots 18, 20, aligner 16, and transfer mechanism 22; pumping and venting of load ports; movement of dual pick track robot 29, etc. It is understood that control system 11 may be implemented in any fashion, e.g., using a computer system comprising hardware, software, or a combination of hardware and software. Accordingly, the flows described herein may be controlled via a program product (i.e., software program) that can be executed within control system 11. It is also understood that control system 11 may be implemented in a distributed fashion, such that the processing and/or memory storage associated with control system 11 can be integrated into one or more of the components described herein and/or reside remotely, e.g., on a network.

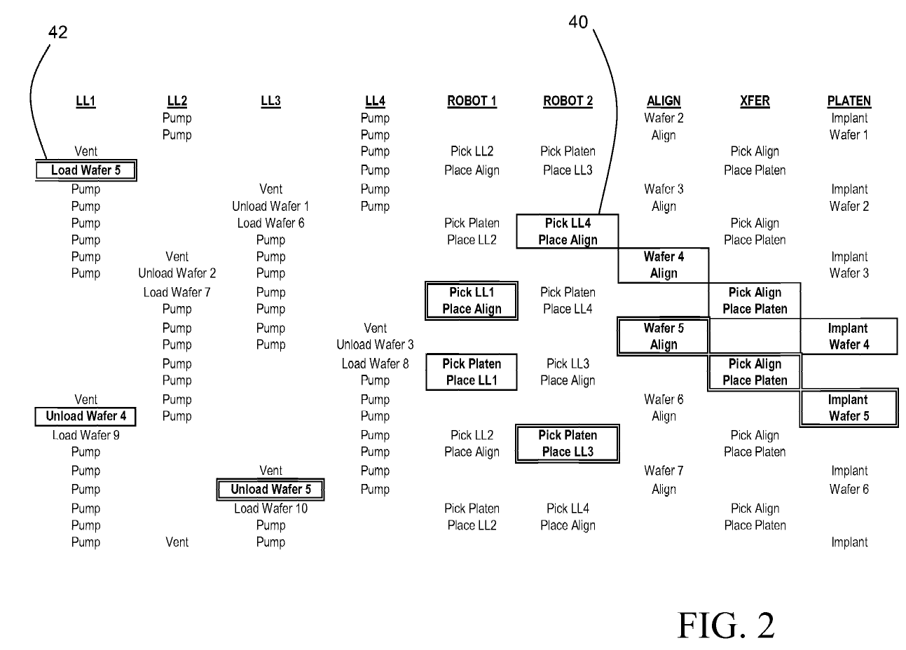

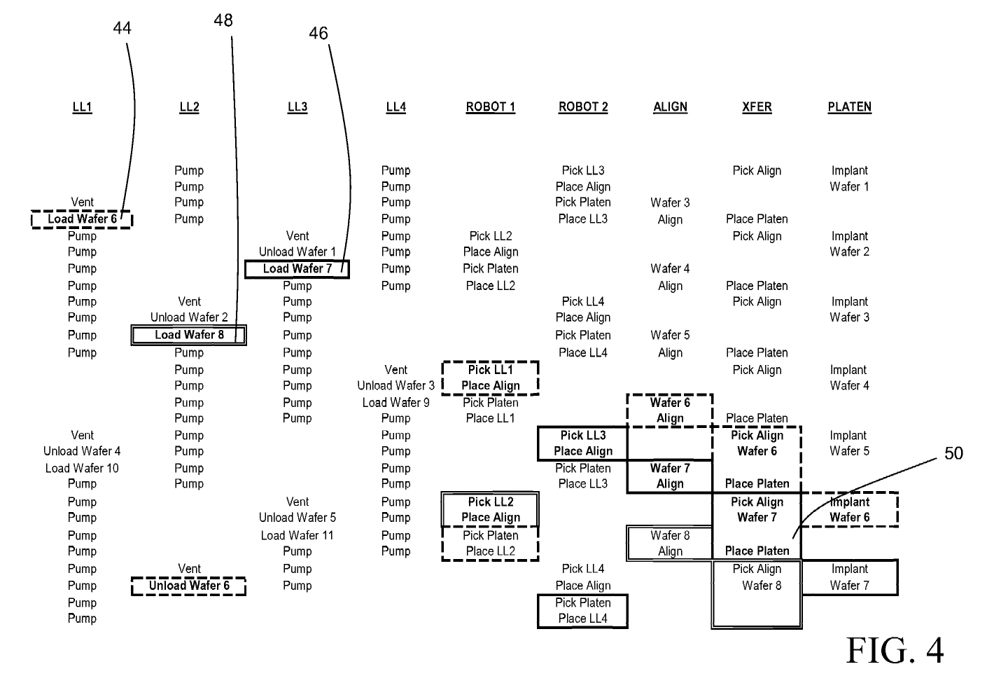

The substrate handler 10 supports at least two substrate flows, both of which can support 500 wafers per hour (wph). FIGS. 2 and 4 depict substrate flow timing diagrams that handle substrates in vacuum chamber 12. In both FIGS. 2 and 4, the x-axis depicts the relevant components of the substrate handler 10, while the y-axis depicts elapsed time from top to bottom.

In the first substrate flow (FIGS. 1 and 2), substrates that enter vacuum chamber 12 through the first dual single wafer load lock 24, i.e., LL1 and LL2, are removed from vacuum chamber 12 through the second dual single wafer load lock 26, i.e., LL3 and LL4. Substrates that enter vacuum chamber 12 through the second dual single wafer load lock 26, i.e., LL3 and LL4 are removed from vacuum chamber 12 through the first dual single wafer load lock 24, i.e., LL1 and LL2.

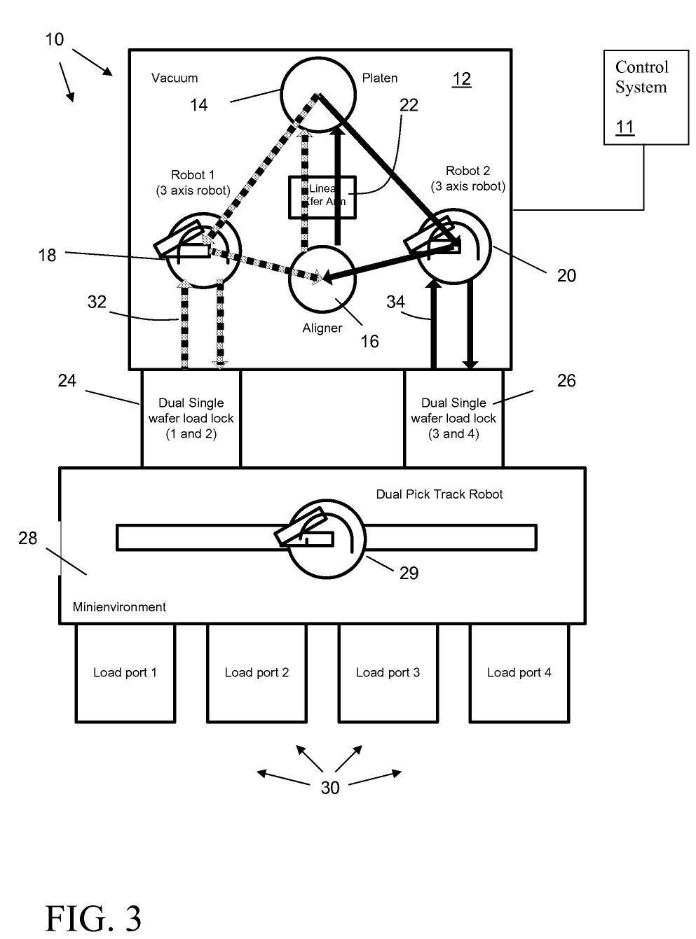

In the second substrate flow (FIGS. 3 and 4), substrates that enter vacuum chamber 12 through the first dual single wafer load lock 24, i.e., LL1 and LL2, are removed from vacuum chamber 12 through the first dual single wafer load lock 24, i.e., LL1 and LL2. Substrates that enter vacuum chamber 12 through the second dual single wafer load lock 26, i.e., LL3 and LL4 are removed from vacuum chamber 12 through the second dual single wafer load lock 26, i.e., LL3 and LL4.

The transfer mechanism 22 (i.e., “XFER”) that transfers substrates from aligner 16 to process platen 14 is used to reduce the workload on the two main vacuum robots 18, 20 to maximize throughput.

Actions relevant to Wafers 4 and 5 are highlighted in FIG. 2 to illustrate the flow. (Reference to the elements in FIG. 1 is also made.) Actions for Wafer 4 are highlighted in a single box 40 and actions for Wafer 5 are highlighted in a double box 42. Although not shown in the timing diagram, Wafer 4 is initially in load lock 4 (LL4). The first action in the timing diagram loads Wafer 5 into LL1. Subsequently, Wafer 4 is picked out of LL4 by Robot 2 and placed into the aligner 16, and is then aligned by the aligner 16. During the same time interval, Wafer 4 is picked out of the aligner and placed onto the platen by the transfer mechanism 22 and Wafer 5 is picked out of LL1 and placed into the aligner 16 by Robot 1. During the next time interval, Wafer 5 is aligned and Wafer 4 is processed. Subsequently, Robot 1 picks Wafer 4 off of process platen 14 and places it into LL1 at the same time Wafer 5 is transferred from aligner 16 to process platen 14 by the transfer mechanism 22. Wafer 4 is then unloaded while Wafer 5 is processed, e.g., implanted. Robot 2 then picks Wafer 5 from process platen 14 to LL3, and finally Wafer 5 is unloaded. This method of processing wafers from alternating sides through a common aligner, transfer mechanism and platen is repeated without interruption for any number of wafers. In addition, the substrate flow is not interrupted when transitioning from one substrate carrier to the next.

In this illustrative embodiment, each cycle in the timing diagram represents 1.75 seconds, resulting in a throughput of 500 wph. However, the described actions may be optimized to increase throughput. The process flow shown in FIG. 2 may be preferable in cases where the vacuum robots 18, 20 are limiting throughput.

FIGS. 3 and 4 depict an alternative substrate flow that provides for the simultaneous handling of three substrates in the vacuum chamber 12. FIG. 3 shows the substrate handler 10 with solid and dashed lines depicting substrate movement, and FIG. 4 depicts the related timing diagram. The substrate flow is similar to the flow shown in FIG. 2, except that a third substrate is temporarily “stored” on the transfer mechanism 22 in the vacuum chamber 12. This substrate flow may be preferable in cases where the load lock pump and vent times are limiting throughput.

Highlighted in FIG. 4 in dotted box 44, line box 46 and double line box 46 are actions relevant to Wafers 6, 7 and 8, respectively. This flow uses twice as much time (i.e., two cycles) to move a wafer from the aligner 16 to the process platen 14. During that time, the wafer is temporarily stored on the transfer mechanism 22 while two other wafers are being handled. For instance, box 50 in FIG. 4 shows that Wafer 7 is picked from Aligner 16, temporarily stored (for an extra cycle) on the transfer mechanism 22, and then placed on the process platen 14. During this same two cycle time period, Wafer 6 is implanted on the process platen 14 and Wafer 8 is aligned by aligner 16. The process flow shown in FIGS. 3 and 4 may be preferable in cases where the load locks 24, 26 are limiting throughput.

Obviously, other substrate flows could be utilized by substrate handler 10 without departing from the scope of the invention. Moreover, substrate handler 10 can be scaled by removing from operation two load locks (e.g., LL3 and LL4), a vacuum robot (e.g., Robot 2), two load ports (e.g., 3 and 4) and the atmospheric track utilized in mini-environment 28. This cost reduced configuration would have a slightly different substrate flow and lower throughput.

Illustrative timing throughputs for these flows are as follows:

A. Platen Throughput
7 sec per substrate
3.5 sec Process
3.5 sec Unload/Load
B. Flow 1 (Two Substrates in Vacuum)—28 Seconds per Loadlock Cycle

| | | |
|---|---|---|
| Vent | 3.5 | sec (<2 sec demonstrated) |
| Unload/Load | 4 | sec |
| Pump | 10 | sec (<7 sec demonstrated) |
| Wait | 10.5 | sec |

C. Flow 2 (Three Substrates in Vacuum)—28 Seconds per Loadlock Cycle

| | | |
|---|---|---|
| Vent | 3.5 | sec (<2 sec demonstrated) |
| Unload/Load | 4 | sec |
| Pump | 13.5 | sec (<7 sec demonstrated) |
| Wait | 7.0 | sec |

D. Aligning<4 sec

E. Pick/Place<2 sec

As noted, the systems, functions, mechanisms, methods, engines and modules described herein can be implemented via control system 11 in hardware, software, or a combination of hardware and software. They may be implemented by any type of computer system or other apparatus adapted for carrying out the methods described herein. A typical combination of hardware and software could be a general-purpose computer system with a computer program that, when loaded and executed, controls the computer system such that it carries out the methods described herein. Alternatively, a specific use computer, containing specialized hardware for carrying out one or more of the functional tasks of the invention could be utilized. In a further embodiment, part or all of the invention could be implemented in a distributed manner, e.g., over a network such as the Internet.

The present invention can also be embedded in a computer program product, which comprises all the features enabling the implementation of the methods and functions described herein, and which—when loaded in a computer system—is able to carry out these methods and functions. Terms such as computer program, software program, program, program product, software, etc., in the present context mean any expression, in any language, code or notation, of a set of instructions intended to cause a system having an information processing capability to perform a particular function either directly or after either or both of the following: (a) conversion to another language, code or notation; and/or (b) reproduction in a different material form.

The foregoing description of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of this invention as defined by the accompanying claims.

1. A substrate handler, having a vacuum chamber for processing a substrate in a controlled environment, the substrate handler comprising:
a first robot configured for transferring substrates from a first set of load locks to a preprocessing station, and for transferring substrates from a process platen to the first set of load locks;
a second robot configured for transferring substrates from a second set of load locks to the preprocessing station, and for transferring substrates from the process platen to the second set of load locks; and
a transfer mechanism for transferring substrates from the transfer station to the process platen.

2. The substrate handler of claim 1, wherein the first and second robot each comprise a 3-axis robot.

3. The substrate handler of claim 1, wherein the preprocessing station includes a preprocessing device selected from the group consisting of an aligner and an orientor.

4. The substrate handler of claim 1, wherein the preprocessing station comprises a transfer station.

5. The substrate handler of claim 1, further comprising a dual pick track robot that transfers substrates between at least one load port and at least one set of load locks.

6. The substrate handler of claim 1, wherein the transfer mechanism comprises a linear transfer arm.

7. The substrate handler of claim 1, wherein the first robot removes substrates from the process platen that were placed on the preprocessing station by the second robot, and the second robot removes substrates from the process platen that were placed on the preprocessing station by the first robot.

8. The substrate handler of claim 1, wherein the first robot removes substrates from the process platen that were placed on the preprocessing station by the first robot, and the second robot removes substrates from the process platen that were placed on the preprocessing station by the second robot.

9. The substrate handler of claim 1, wherein the transfer mechanism is utilized to temporarily store a substrate while two other substrates are handled within the vacuum chamber.

10. The substrate handler of claim 1, wherein the first and second set of load locks each comprise dual single wafer load locks such that each robot can access two load locks.

11. The substrate handler of claim 1, further comprising a scalable configuration in which one of the robots and associated set of load locks are removed from operation.

12. A method of handling substrates in a chamber, comprising:
loading a first substrate from a first set of load locks to a preprocessing station using a first robot;
preprocessing the first substrate on the preprocessing station;
moving the first substrate to a process platen using a transfer mechanism;
loading a second substrate from a second set of load locks to the preprocessing station using a second robot;
preprocessing the second substrate on the preprocessing station;
processing the first substrate on the process platen;
moving the first substrate to the second set of load locks using the second robot;
moving the second substrate to the process platen using the transfer mechanism;
processing the second substrate on the process platen; and
moving the second substrate to the first set of load locks using the first robot.

13. The method of claim 12, wherein preprocessing is selected from the group consisting of: aligning and orienting.

14. The method of claim 12, wherein the preprocessing station comprises a transfer station.

15. The method of claim 12, wherein moving the first substrate to the process platen using the transfer mechanism and loading the second substrate from the second load lock to the preprocessing station using the second robot occur simultaneously.

16. The method of claim 12, wherein preprocessing the second substrate on the preprocessing station and processing the first substrate on the process platen occur simultaneously.

17. The method of claim 12, wherein moving the first substrate to the second set of load locks using the second robot and moving the second substrate to the process platen using the transfer mechanism occur simultaneously.

18. The method of claim 12, wherein the first and second set of load locks each comprise dual single wafer load locks such that each robot can access two load locks.

19. A method of handling substrates in a chamber, comprising:
loading a first substrate from a first set of load locks to a preprocessing station using a first robot;
preprocessing the first substrate on the preprocessing station;
picking the first substrate off the preprocessing station and storing the first substrate on a transfer mechanism;
loading a second substrate from a second set of load locks to the preprocessing station using a second robot;
preprocessing the second substrate on the preprocessing station;
placing the first substrate onto a process platen from the transfer mechanism;
picking the second substrate off the preprocessing station and storing it on the transfer mechanism;
loading a third substrate from the first set of load locks to the preprocessing station using the first robot; and
processing the first substrate on the process platen.

20. The method of claim 19, further comprising:
moving the first substrate to the first set of load locks using the first robot;
placing the second substrate onto a process platen from the transfer mechanism; and
processing the second substrate on the process platen.

21. The method of claim 20, further comprising:
picking the third substrate off the preprocessing station and storing it on the transfer mechanism; and
moving the second substrate to the second set of load locks using the second robot.

22. The method of claim 19, wherein preprocessing is selected from the group consisting of: aligning and orienting.

23. The method of claim 19, wherein the preprocessing station comprises a transfer station.

24. The method of claim 19, wherein the first and second set of load locks each comprise dual single wafer load locks such that each robot can access two load locks.

25. The method of claim 19, wherein picking the first substrate off the preprocessing station and storing it on the transfer mechanism and loading the second substrate from a second set of load locks to the preprocessing station using a second robot occur simultaneously.

26. The method of claim 19, wherein picking the second substrate off the preprocessing station and storing it on the transfer mechanism and processing the first substrate on the process platen occur simultaneously.

27. The method of claim 19, wherein an aligning of the third substrate occurs simultaneously with placing the second substrate onto the process platen from the transfer mechanism.

28. The method of claim 21, wherein processing of the second substrate on the process platen and picking the third substrate off the preprocessing station and storing it on the transfer mechanism occur simultaneously.

29. A program product stored on a computer readable medium, which when executed controls the flow of substrates within a substrate handler, the program product comprising:
program code configured for causing a first robot to transfer substrates from a first set of load locks to a preprocessing station, and to transfer substrates from a process platen to the first set of load locks;
program code configured for causing a second robot to transfer substrates from a second set of load locks to the preprocessing station, and to transfer substrates from the process platen to the second set of load locks;
program code configured for causing a transfer mechanism to transfer substrates from the preprocessing station to the process platen; and
program code configured for pumping and venting the first and second set of load locks.
